(19) United States
(12) Patent Application Publication
(10) Pub. No.: US 2025/0037755 A1
(43) Pub. Date: Jan. 30, 2025

(54) SELECTION CIRCUITRY

(71) Applicant: Micron Technology, Inc., Boise, ID (US)

(72) Inventors: Timothy P. Finkbeiner, Boise, ID (US); Glen E. Hush, Boise, ID (US); Troy A. Manning, Meridian, ID (US); Troy D. Larsen, Meridian, ID (US); Peter L. Brown, Eagle, ID (US)

(21) Appl. No.: 18/763,395

(22) Filed: Jul. 3, 2024

Related U.S. Application Data
(60) Provisional application No. 63/528,514, filed on Jul. 24, 2023.

(51) Int. Cl. G11C 11/4091; G11C 11/4093; H03K 19/20

(52) U.S. Cl. CPC G11C 11/4091; G11C 11/4093; H03K 19/20

(57) ABSTRACT

Methods and apparatuses related to using non-zero selection circuitry. For example, the non-zero selection circuitry can determine whether a first word received from a first group of sense amplifiers has at least one bit having a first binary value, such as a logical “1”. In response to the first word being determined to have at least one bit having the first binary value, the first word can be outputted from the non-zero selection circuitry and a second word can be prevented from being outputted (even if the second word is determined to have at least one bit having the first binary value) at least while the first word is being outputted.

### TECHNICAL FIELD

This application claims the benefit of U.S. Provisional Application No. 63/528,514, filed on Jul. 24, 2023, the contents of which are incorporated herein by reference.

### TECHNICAL FIELD

The present disclosure relates generally to semiconductor memory and methods, and more particularly, to apparatuses, systems, and methods related to selection circuitry.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes Random Access Memory (RAM), Dynamic Random Access Memory (DRAM), Static Random Access Memory (SRAM), Synchronous Dynamic Random Access Memory (SDRAM), and Thyristor Random Access Memory (TRAM), among others. Non-volatile memory can provide persistent data by retaining stored data when not powered and can include NAND flash memory, NOR flash memory, Ferroelectric Random Access Memory (FeRAM), and resistance variable memory such as Phase Change Random Access Memory (PCRAM), Resistive Random Access Memory (RRAM), and Magnetoresistive Random Access Memory (MRAM), such as Spin Torque Transfer Random Access Memory (STTRAM), among others.

Electronic systems may include processing resources (e.g., one or more processors), which may retrieve and execute instructions and store the results of the executed instructions to a suitable location. A processor may include functional units such as arithmetic logic unit (ALU) circuitry, floating point unit (FPU) circuitry, and/or a combinatorial logic block, for example, which may be used to execute instructions by performing logical operations such as AND, OR, NOT, NAND, NOR, and XOR, and invert (e.g., inversion) logical operations on data (e.g., one or more operands).

### BRIEF DESCRIPTION OF THE DRAWINGS

FIG. 1 illustrates a block diagram in the form of a memory system including a memory device having an array coupled to selection circuitry in accordance with a number of embodiments of the present disclosure.

FIG. 2 is a schematic diagram illustrating a memory array coupled to selection circuitry in accordance with a number of embodiments of the present disclosure.

FIG. 3 is a functional block diagram illustrating non-zero selection circuitry including multiple circuit blocks in accordance with a number of embodiments of the present disclosure.

FIG. 4 is a schematic diagram illustrating at least a portion of non-zero selection circuitry including circuit blocks in accordance with a number of embodiments of the present disclosure.

FIG. 5 is a flow diagram that illustrates an example method for using selection circuitry in accordance with various embodiments of the present disclosure.

### DETAILED DESCRIPTION

Systems, apparatuses, and methods related to selection circuitry are described. As an example, a method can include: determining, at selection circuitry, whether a first word received from a first group of sense amplifiers has at least one bit having a first binary value; and, at least while the first word is being outputted from the selection circuitry responsive to the first word being determined to have the at least one bit having the first binary value, preventing a selector configured to receive a second word from a second group of sense amplifiers from outputting the second word from the selection circuitry regardless of whether the second word has at least one bit having the first binary value. The selection circuitry can be “non-zero” selection circuitry configured to identify when a word comprises one or more non-zero bits.

As used herein, the term “word” refers to unit of data generally handled as a single entity and having a particular size in terms of a quantity of bits. Often, a word with constituent bits all having logical “0”s (alternatively referred to as “zero word”) may not represent actual data values; thereby, indicating absence of valid data. Even if a zero word represents an actual numerical value of “0”, this numerical value may sometimes be desired to be ignored when such a value does not contribute to a mathematical operation, for example. For example, if one or more addition operations are desired to be performed on multiple words, a zero word representing a numerical value of “0” does not affect a result of the addition operations (because the result remains unchanged even if a numerical value of “0” is added); thereby, making use of the zero word unnecessary for the addition operations. Therefore, it may be desirable that these zero words (representing either non-valid data or numerical value of “0”) are often not transferred out of a memory array, such as from sense amplifiers, once the words are determined to be zero words.

Accordingly, a number of embodiments of the present disclosure provide non-zero selection circuitry that is designed to ignore zero words among those words received from sense amplifiers. For example, the non-zero selection circuitry performs a search process for any non-zero words among those words received as inputs from sense amplifiers. This search process is “sequential” in that words input to the non-zero selection circuitry are sequentially examined to determine whether a respective word is a non-zero or not. Further, this process is “automatic” in that (once the non-zero selection circuitry is enabled) multiple words are sequentially searched without further external intervention/signaling (e.g., from a controller external to the memory array) that would have been provided for examining each input word according to prior approaches. The search process can continue until a non-zero word among the words is identified. At this point, a non-zero word is replaced with a zero word once the non-zero word is transferred out of the sense amplifiers so as to cause non-zero selection circuitry to perform a search process on the other words. In embodiments of the present disclosure, system resources can be conserved by not transferring zero words, which can avoid consumption of unnecessary power and bandwidth of the memory system. Further, latencies associated with transferring words to the host can be reduced, leading to improved system performance.

As used herein, the singular forms “a,” “an,” and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” As used herein, “coupled to” or “coupled with” generally refers to a connection between components, which can be an indirect communicative connection or direct communicative connection (e.g., without intervening components), whether wired or wireless, including connections such as electrical, optical, magnetic, and the like. The terms “data” and “data values” are used interchangeably herein and can have the same meaning, as appropriate to the context.

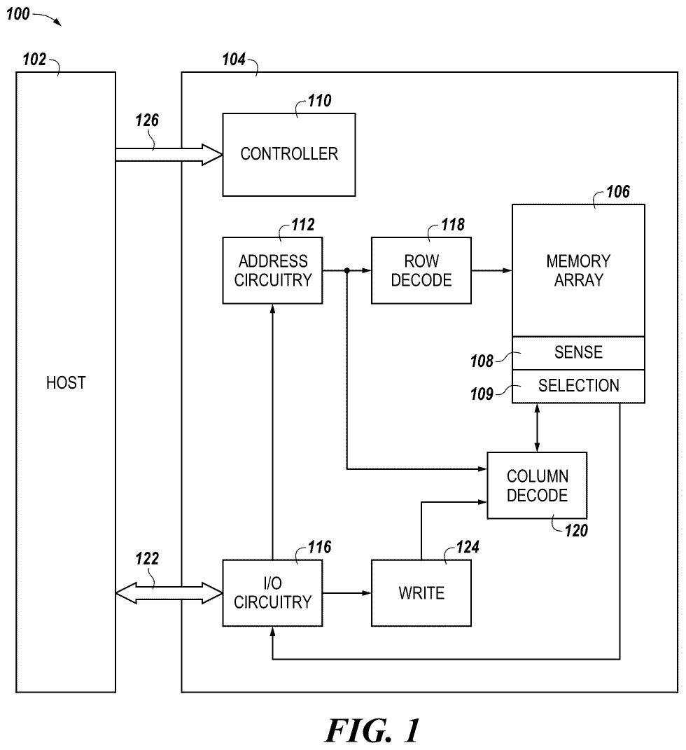

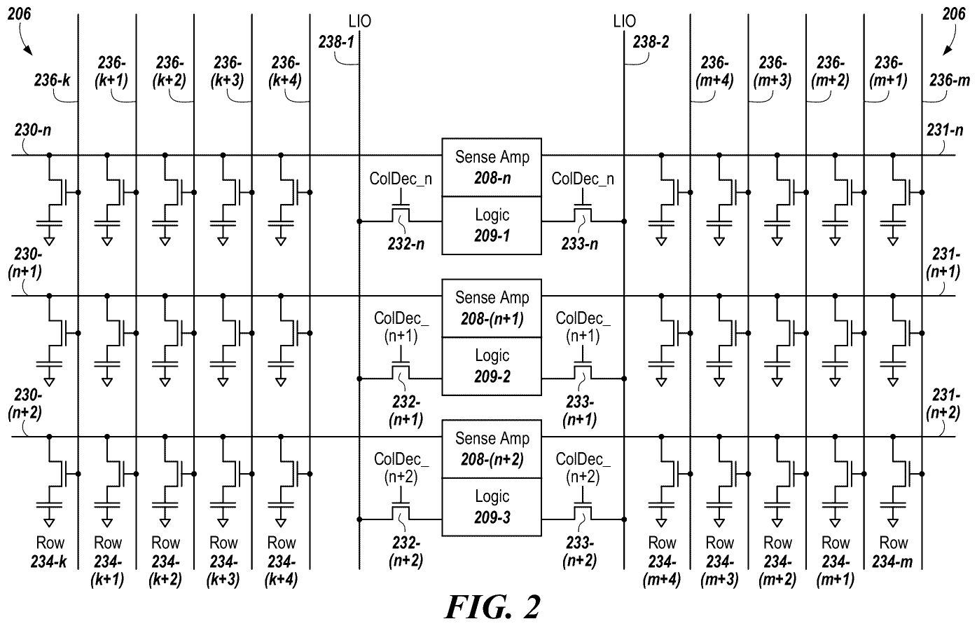

The figures herein follow a numbering convention in which the first digit or digits correspond to the drawing figure number and the remaining digits identify an element or component in the drawing. Similar elements or components between different figures may be identified by the use of similar digits. For example, element 108 can represent element 8 in FIG. 1, and a similar element can be labeled 208 in FIG. 2. Analogous elements within a figure may be referenced with a hyphen and extra numeral or letter. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an apparatus in the form of a memory system 100 including a memory device having an array 106 coupled to selection circuitry 109 in accordance with a number of embodiments of the present disclosure. As used herein, a memory device 104, a memory array 106, sense amplifiers (“SA” in FIG. 1) 108, and/or selection circuitry (“selection” in FIG. 1) 109 might also be separately considered an “apparatus.” Although the example shown in FIG. 1 illustrates a system having a Von Neumann architecture, embodiments of the present disclosure can be implemented in non-Von Neumann architectures (e.g., a Turing machine), which may not include one or more components (e.g., CPU, ALU, etc.) often associated with a Von Neumann architecture.

The computing system 100 includes a host 102 coupled (e.g., connected) to the memory device 104, which includes the memory array 106. The computing system 100 can be a component or a resource of a personal laptop computer, a desktop computer, a digital camera, a smart phone, or a memory card reader, for example, among various other types of electronic devices. The host 102 can be or include a processing device, such as an CPU. The host 102 can include a system motherboard and/or backplane and can include one or more processing devices (e.g., one or more processors such as an CPU, microprocessors, controlling circuitry). The computing system 100 can include the host 102 and the memory device 104 as separate and distinct integrated circuits or the host 102 and the memory device 104 as components on the same (a single) integrated circuit (e.g., the host 102 on-chip with the memory device 104). In some embodiments, the memory device 104 can include components coupled to respective substrates and those substates can be coupled to another substrate, such as a printed circuit board (PCB). The computing system 100 can be, for instance, a component or a resource of a server system and/or a high performance computing (HPC) system and/or a portion thereof.

The memory array 106 can be a DRAM array, SRAM array, STT RAM array, PCRAM array, TRAM array, RRAM array, FeRAM array, NAND flash array, and/or NOR flash array, for instance. A FeRAM array can include ferroelectric capacitors and can perform bit storage based on an amount of voltage or charge applied thereto. The memory array 106 can comprise memory cells arranged in rows coupled by access lines (which may be referred to herein as word lines or select lines) and columns coupled by sense lines. Although a single memory array 106 is shown in FIG. 1, embodiments are not so limited. For instance, the memory device 104 can include one or more memory arrays 106 (e.g., a number of banks of DRAM cells).

The memory device 104 can include address circuitry 112 to latch address signals provided over an I/O bus 122 (e.g., a data bus) through I/O circuitry 116. Address signals can be received and decoded by a row decoder 118 and a column decoder 120 to access the memory array 106. Data can be read from the memory array 106 by sensing voltage and/or current changes on the digit lines using the sense amplifiers 108. As described herein, the sense amplifiers 108 can be one or more sense amplifier stripes. The sense amplifiers 108 can be used to read and latch a page (e.g., row) of data from the memory array 106. The I/O circuitry 116 can be used for bi-directional data communication with the host 102 over the I/O bus 122. The write circuitry 124 can be used to write data to the memory array 106.

A controller 110 can decode signals provided by a control bus 126 from the host 102. These signals can include chip enable signals, write enable signals, and address latch signals that are used to control operations performed on the memory array 106, including data read, data write, and data erase operations. In various embodiments, the controller 110 can be responsible for executing instructions from the host 102. The controller 110 can be a state machine, a sequencer, or some other type of controller.

In some embodiments, the sense amplifiers 108 can be used to perform logical operations using data stored in the memory array 106 and/or data stored in the sense amplifiers 108 as inputs and store the results of the logical operations the memory array 106 and/or data stored in the sense amplifiers 108 without transferring data via a sense line address access (e.g., without firing a column decode signal). As such, various compute functions can be performed using, and within, the sense amplifiers 108 rather than (or in association with) being performed by processing resources external to the sense amplifiers 108 (e.g., by a processor associated with the host 102 and/or other processing circuitry, such as ALU circuitry, of the memory device 104 (e.g., of the controller 110 or elsewhere)).

The selection circuitry 109 can be coupled to sense amplifiers 108. The selection circuitry 109 can perform a search process on words received from sense amplifiers 108 to selectively output words that have at least one particular binary value (e.g., to the host 102), while ignoring (e.g., not outputting) the other words that do not included the particular binary value (e.g., at all) among the words received from sense amplifiers 108. Although embodiments are not so limited, the particular binary value can be a logical “1”. Each search process can halt when one zero word is found among the words (e.g., received from sense amplifiers 108). At this point, the search process can resume when the searched non-zero word is replaced (e.g., by the controller 110) with a zero word, which can be ignored when the search process is resumed. Further details of selection circuitry 109 and the search process are described in connection with FIGS. 2-5.

FIG. 2 is a schematic diagram illustrating a memory array 206 coupled to selection circuitry (e.g., the selection circuitry 109 as illustrated in FIG. 1) in accordance with a number of embodiments of the present disclosure. The logic circuits 209-1, 209-2, 209-3 (collectively referred to as logic circuits 209) can be part of selection circuitry 109 illustrated in FIG. 1.

The memory array 206 includes a first subset including rows of memory cells 234-m, 234-(m+1), 234-(m+2), 234-(m+3), and 234-(m+4) coupled to respective word lines (e.g., 236-m, 236-(m+1), 236-(m+2), 236-(m+3), and 236-(m+4), respectively). The memory array 206 includes a second subset portion including rows of memory cells 234-k, 234-(k+1), 234-(k+2), 234-(k+3), and 234-(k+4) coupled to respective word lines (e.g., 236-k, 236-(k+1), 236-(k+2), 236-(k+3), and 236-(k+4), respectively). As used herein, “subset” is used for identification purposes and does not necessarily imply physical or logical characteristics (e.g., boundaries) of the memory array 206. The rows of the subarrays are referred to collectively as the rows 234 and the word lines of the subarrays are referred to collectively as the word lines 236.

The memory array 206 includes columns of memory cells corresponding respective complementary digit line pairs 230-n/231-n, 230-(n+1)/231-(n+1), and 230-(n+2)/231-(n+2). The columns of memory cells include respective sense amplifiers 208-n, 208-(n+1), and 208-(n+2) (referred to collectively as the sense amplifiers 208) that can be operated in multiple modes in accordance with embodiments described herein. The memory array 206 and the sense amplifiers 208 can be analogous to the memory array 106 and the sense amplifiers 108 described in association with FIG. 1. Although FIG. 2 illustrates five word lines 236 (e.g., five rows 234) coupled to a local I/O line (e.g., LIO 238-1 and LIOF 238-2) via three digit lines 230 and three sense amplifiers 208 (e.g., three columns), embodiments can include greater or fewer than five word lines and greater or fewer than three digit lines coupled to a local I/O line. Also, FIG. 2 illustrates the complementary digit line pairs 230-n/231-n, 230-(n+1)/231-(n+1), and 230-(n+2)/231-(n+2) in an open digit line architecture; however, embodiments can include a folded digit line architecture, for example.

In this example, the memory array 206 includes ITIC (one transistor one capacitor) DRAM memory cells with each memory cell including an access device (e.g., a transistor) and a storage element (e.g., a capacitor). In some embodiments, the memory cells can be destructive read memory cells (e.g., reading data stored in a memory cell destroys the data such that the data originally stored in the memory cell is refreshed after being read).

FIG. 2 illustrates an example configuration for the sense amplifiers 208 described herein (illustrated schematically by the sense amplifier 208-n). Embodiments of the present disclosure are not limited to the example sense amplifier configuration illustrated by FIG. 2, and can be, for example, a current-mode sense amplifier and/or a single-ended sense amplifier (e.g., a sense amplifier coupled to a single digit line).

Column decoder transistors 232-n and 233-n are coupled to the sense amplifier 208-n, column decoder transistors 232-(n+1) and 233-(n+1) are coupled to the sense amplifier 208-n+1, and column decoder transistors 232-n+2 and 233-n+2 are coupled to the sense amplifier 208-n+2. The columns of memory cells include corresponding respective column decode transistor pairs (e.g., 232-n and 233-n, 232-(n+1) and 233-(n+1), 232-(n+2) and 233-(n+2) (referred to collectively as the column decode transistors of 232 and 233)) that can be operated via respective column decode signals (e.g., ColDec_n, ColDec_(n+1), and ColDec_(n+2), respectively). For example, one or more of the column decode transistors 232 and 233 can be enabled to transfer, via local I/O lines LIO 238-1 and LIOF 238-2, data values from corresponding sense amplifiers 208 and/or selection circuitry (that includes logic circuits 209) to a component external to the memory array 206, such as the host 102 described in association with FIG. 1.

In some embodiments, the memory array 206 can include one or more subarrays. As used herein, “subarray” refers to a subset of a memory array (e.g., the memory array 206). In some embodiments, rows and columns of a memory array coupled to a local I/O line can correspond to a subarray. For example, the word lines 236-m, 236-(m+1), 236-(m+2), 236-(m+3), and 236-(m+4) and the digit lines 230-n, 230-(n+1), and 230-(n+2), and the memory cells coupled thereto, can correspond to a subarray. The word lines 236-k, 236-(k+1), 236-(k+2), 236-(k+3), and 236-(k+4) and the digit lines 231-n, 231-(n+1), and 231-(n+2), and the memory cells coupled thereto, can correspond to another subarray. In some embodiments, the memory array 206 can be a bank. As used herein, “bank” refers a memory array of a memory device, such as the memory device 104 described in association with FIG. 1.

Although not illustrated by FIG. 2, the local I/O lines LIO 238-1 and LIOF 238-2 can be coupled to one or more I/O lines (e.g., global I/O lines) that provide communication between the memory array 206 and one or more components external to the memory array 206. In some embodiments, a multiplexer can couple multiple local I/O lines of the memory array 206 to a global I/O line. In some embodiments, a multiplexer can be coupled to multiple global I/O lines. For example, eight global I/O lines can be coupled to a multiplexer where each global I/O line coupled thereto provides a respective bit of a byte of data to be transferred to or from the memory array 206.

The sense amplifiers 208 and logic circuits 209 can be electrically connected to the LIO 238-1 via the column decoder transistors 232-n, 232-(n+1), and 232-(n+2). The sense amplifiers 208 and logic circuits 209 can be connected to the LIOF 238-2 via the column decoder transistors 233-n, 233-(n+1), and 233-(n+2). In some embodiments, the column decode transistors 232 and 233 can be coupled to respective sense amplifiers 208 (and respective logic circuits 209) and respective complementary digit line pairs 230-n/231-n, 230-(n+1)/231-(n+1), and 230-(n+2)/231-(n+2) such that disabling one or more of the column decode transistors 232 and 233 electrically connects and disconnects the sense amplifiers 208 and logic circuits 209 from the LIO 238-1 and/or the LIOF 238-2. One or more of the column decode transistors 232 and 233 can be enabled to transfer a signal corresponding to a state (e.g., a logical data value such as logic “0” or logic “1”) of a memory cell and/or a logical data value stored by the sense amplifiers 208 to the LIO 238-1 and/or the LIOF 238-2.

The column decoder transistors 232 and 233 can be coupled to a column decoder (e.g., the column decoder 120 described in association with FIG. 1). The sense amplifiers 208 and logic circuits 209 can be electrically connected to the LIO 238-1 and/or the LIOF 238-2 via the column decoder transistors 232 and 233 in association with operating the sense amplifiers 208 in a sense amplifier mode.

The sense amplifiers 208 can be operated to determine a data value (e.g., logic state) stored in a memory cell and/or represented by voltages present on the complementary digit line pairs 230-n/231-n, 230-(n+1)/231-(n+1), and 230-(n+2)/231-(n+2). Further, the sense amplifiers 208 can be operated to perform logical functions. Although not illustrated in FIG. 2, the sense amplifiers 208 can each include cross coupled p-channel transistors (e.g., PMOS transistors) and cross coupled n-channel transistors (e.g., NMOS transistors).

When a memory cell is being sensed (e.g., read), the voltage on a digit line of one of the complementary digit line pairs 230-n/231-n, 230-(n+1)/231-(n+1), and 230-(n+2)/231-(n+2) can be slightly greater than the voltage on the other digit line of the pair. A positive control signal (e.g., ACT signal) can then be driven high and the Rn1F signal can be driven low to enable one or more of the sense amplifiers 208. The digit line of the pair having the lower voltage will turn on one of the PMOS transistors to a greater extent than the other of the PMOS transistors. As a result, the digit line of the pair having the higher voltage is driven high to a greater extent than the other digit line.

Similarly, the digit line of one of the complementary digit line pairs 230-n/231-n, 230-(n+1)/231-(n+1), and 230-(n+2)/231-(n+2) having the higher voltage will turn on one of he NMOS transistor to a greater extent than the other of the NMOS transistor. As a result, the digit line of the pair having the lower voltage is driven low to a greater extent than the other digit line. After a short delay, the digit line of the pair having the greater voltage can be driven to the voltage of the supply voltage (e.g., V_{DD}) and the other digit line can be driven to the voltage of the reference voltage (e.g., ground). Therefore, the NMOS transistors and the PMOS transistors serve as a sense amplifier pair that amplify the voltage differential on the complementary digit line pairs 230-n/231-n, 230-(n+1)/231-(n+1), and 230-(n+2)/231-(n+2) and operate to latch a data value sensed from the memory cell.

The logic circuits 209 can operate in a collective manner to select and output a non-zero word among those logical words stored in the sense amplifiers 208. Although embodiments are not so limited, a word can include 8 bits (1 byte), 16 bits (2 bytes), 32 bits (4 bytes), 64 bits (8 bytes), etc. For example, assuming that a word includes 16 bits, a single word can be input to logic circuits (e.g., logic circuits 309) from sixteen sense amplifiers (e.g., sense amplifiers 208). Words input to logic circuits (e.g., logic circuits 309) respectively from groups of sense amplifiers (e.g., each group corresponding to a single word) can be sequentially examined to search for a word each word that is non-zero. As used herein, a word is non-zero when the word includes at least one bit having “non-zero” (e.g., logical “1”). Otherwise, a word is referred to as being a “zero” word (e.g., all bits of the word having a logical “0”). This search process is performed until a non-zero word is spotted. At this point, the non-zero word is outputted on the LIO lines 238 to a component external to the memory array 206, such as the host 102 described in association with FIG. 1. Further, a result of this search process is communicated to the controller 110, which then can cause the non-zero word (being input to logic circuits 209 of the selection circuitry) to be replaced with a “zero” word to cause another search process to be performed on the other words. This replacement can be performed in various manners. In one example, the controller 110 can cause particular rows (storing a reference value, such as “0”) to be activated to further cause “0”s to be sensed by corresponding sense amplifiers, which then can provide (e.g., input) “0”s to respective logic circuits 209 of the selection circuitry. In another example, the controller 110 can cause overwriting of memory cells storing the non-zero word with “0”s such that a zero word is sensed by corresponding sense amplifiers (which then can provide the sensed zero word to respective logic circuits 209 the selection circuitry) when the memory cells are read again.

Although not illustrated in FIG. 2, embodiments of the present disclosure can include additional transistors (e.g., NMOS or PMOS transistors) that are dedicated to isolating the sense amplifiers 208 from capacitance of the digit lines 230 and 231. For example, on one side, each of these additional transistors can have a source/drain region coupled to a respective one of the digit lines 230 and another source/drain region coupled to one of the sense amplifiers 208 coupled to that digit line. On the other side, each of these additional transistors can have a source/drain region coupled to a respective one of the digit lines 231 and another source/drain region coupled to one of the sense amplifiers 208 coupled to that digit line. Gates of these additional transistors can be coupled to a signal line by which a control signal can be provided.

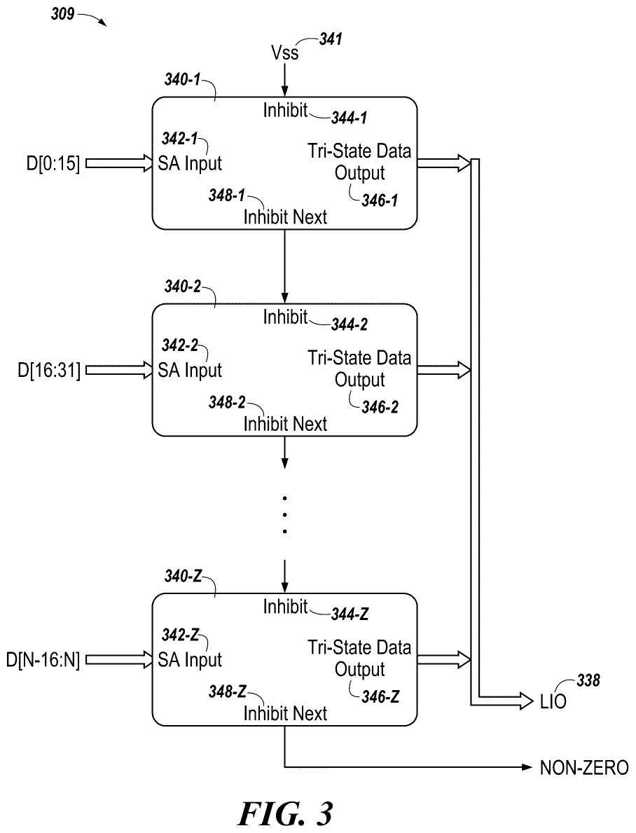

FIG. 3 is a functional block diagram illustrating non-zero selection circuitry 309 including multiple circuit blocks 340-1, 340-2, . . . , 340-Z in accordance with a number of embodiments of the present disclosure. The non-zero selection circuitry 309 is analogous to non-zero selection circuitry 109 illustrated in FIG. 1. Further, the logic circuits 235-n, . . . , 235-(n+2) illustrated in FIG. 2 are part of the non-zero selection circuitry 309.

The non-zero selection circuitry 309 includes multiple circuit blocks 340-1, . . . , 340-Z. Each circuit block can be coupled to a respective group of sense amplifiers (e.g., sense amplifiers 108, 208-n, . . . , 208-(n+2) illustrated in FIGS. 1 and 2, respectively) to receive words from the sense amplifiers. As illustrated in FIG. 3, a circuit block 340-1 can receive a word (having sixteen bits “D[0:15]” shown in FIG. 3) from sixteen sense amplifiers via an input channel 342-1 (“SA Input” shown in FIG. 3), a circuit block 340-2 can receive a word (having sixteen bits “D[16:31]” shown in FIG. 3) from different sixteen sense amplifiers via an input channel 342-2 (“SA Input” shown in FIG. 3), and a circuit block 340-Z can receive a word (having sixteen bits “D[N-16:N]” shown in FIG. 3) from different sixteen sense amplifiers via an input channel 342-Z (“SA Input” shown in FIG. 3). These circuit blocks 340-1, . . . , 340-Z can be commonly coupled to the LIO line (e.g., LIO lines 238 illustrated in FIG. 2), although embodiments are not so limited.

Each circuit block 340-1, . . . , 340-Z includes a respective input (e.g., 344-1, 344-2, or 344-Z) channel and a respective output channel (e.g., 348-1, 348-2, or 348-Z) respectively to receive and provide signals (which can be “inhibit” signals). For example, the circuit block 340-1 can receive a signal via the input channel 344-1 (“inhibit” shown in FIG. 3) and provide a signal to the circuit block 340-2 via the output channel 348-1 (“inhibit next” shown in FIG. 3), the circuit block 340-1 can receive a via the input channel 344-1 (“inhibit” shown in FIG. 3) and provide a signal to the next circuit block (not shown) via the output channel 348-1 (“inhibit next” shown in FIG. 3), and the circuit block 340-Z can receive a signal via the input channel 344-Z (“inhibit” shown in FIG. 3) and output a signal via the output channel 348-Z (“inhibit next” shown in FIG. 3).

The first circuit block 340-1 can be configured to receive a ground voltage (“Vss” 341 shown in FIG. 3 and alternatively referred to as “activation signal”), which can be taken as a logical “0”. Once a signal corresponding to the ground voltage is received at the first circuit block 340-1, a search (e.g., for a non-zero word among those words received at the circuit blocks 340) process can begin at the non-zero selection circuitry 309.

The signals received and/or provided respectively via input and/or output channels 344 and 348 can be indicative of whether outputting of corresponding words (from respective circuit blocks 340) on the LIO line 338 (e.g., LIO 238-1 or LIOF 238-2 illustrated in FIG. 2) are allowed or inhibited. For example, a signal received via the input channel 344-1 can be indicative of whether the circuit block 340-1 is allowed to output or inhibited from outputting a “D[0:15]” word via an output channel 346-1 (“Tri-state data output” shown in FIG. 3) and on the LIO line 338, a signal received via the input channel 344-2 from the circuit block 340-1 can be indicative of whether the circuit block 340-2 is allowed to output or inhibited from outputting a “D[16:31]” word via an output channel 346-2 (“Tri-state data output” shown in FIG. 3) and on the LIO line 338, and a signal received at the circuit block 340-Z via the input channel 344-Z can be indicative of whether the circuit block 340-Z is allowed to output or inhibited from outputting a “D[N-16:N]” word via an output channel 346-Z (“Tri-state data output” shown in FIG. 3) and on the LIO line 338. While being inhibited, each circuit block 340 can be prevented from outputting a corresponding word (regardless of whether the corresponding word is a non-zero word or not). As used herein, the signal that causes a respective circuit block (e.g., circuit block 340) to be inhibited can be referred to as “inhibit signal”.

The output channels 346-1, 346-2, . . . , 346-Z can correspond to “tri-state”, which includes three distinct logical states, such as logical high, logical low, and high impedance states. For example, an output channel 346 in a high impedance state does not source or sink current and do not present a signal on the LIO line 338. For example, while one output channel 346 is actively driving signals to output data (e.g., “D[0:15]” “D[16:31]”, and/or “D[N-16:N]” words), the other output channels 346 can be in a “high impedance” state, allowing the output channel 346 drives the signals without interference.

Consider an example, in which a word “D[16:31]” is non-zero, while the other words “D[0:15]”, or “D[N-16:N]” are not. In this example, the circuit block 340-1 puts output channel 346-1 in a high impedance state and the circuit block 340-1 provides a signal to the circuit block 340-2 to allow the circuit block to output a corresponding word (alternatively referred to as “non-tristate” output) when the word is non-zero. Since the word “D[16:31]” is assumed to be non-zero in this example, the circuit block 340-2 outputs (actively drives) the word “D[16:31]” and provides a signal (e.g., an inhibit signal) to a subsequent circuit block (not shown in FIG. 3) to ultimately cause an inhibit signal to be received at the circuit block 340-Z. Upon receiving the inhibit signal, the other circuit blocks (including the circuit block 340-Z) are inhibited at least while the word “D[16:31]” is being outputted (e.g., driven). Further, the circuit block 340-Z outputs a signal on the output channel 348-Z in response to the inhibit signal propagated from the circuit block 340-2. This signal outputted on the output channel 348-Z can be provided to the controller (e.g., the controller 110) and interpreted (e.g., by the controller 110) as a “NON-ZERO” flag, indicating that at least one circuit block of the non-zero selection circuitry 309 is driving a non-tristate output on a corresponding output channel 346. Upon determining that the word “D[16:31]” has been outputted from the non-zero selection circuitry 309 and/or received at the host (e.g., the host 102 illustrated in FIG. 1), the controller (e.g., the controller 110) can cause sixteen bits all having a logical “0” to be input to the circuit block 340-2 via the input channel 342-2, which causes the circuit block 340-2 to put output channel 346-2 in a high impedance state and provide a signal to a subsequent circuit block to allow the subsequent circuit block 340 to output a corresponding word when the word received at the subsequent circuit block 340 is non-zero.

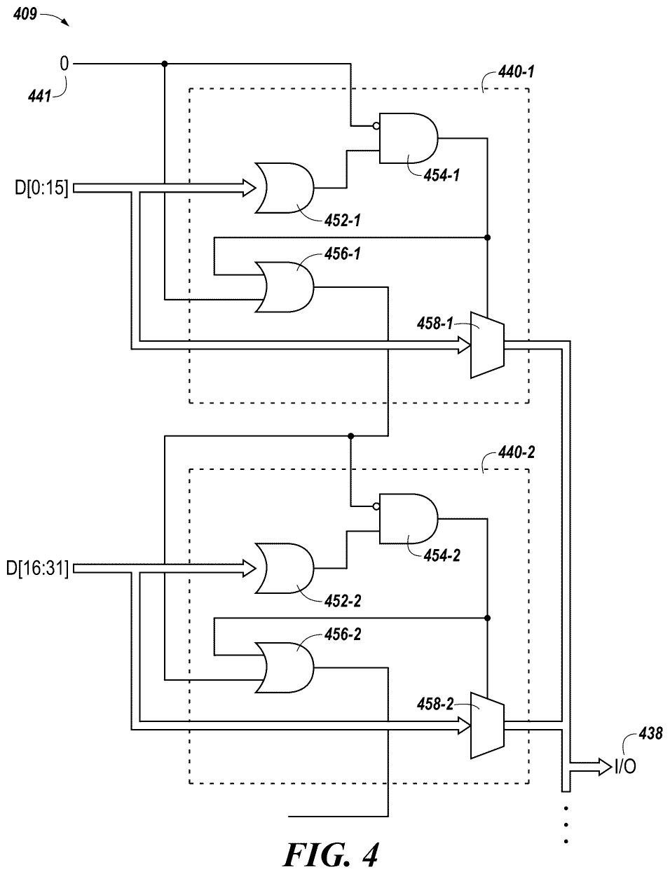

FIG. 4 is a schematic diagram illustrating at least a portion of non-zero selection circuitry 409 including circuit blocks 440-1 and 440-2 in accordance with a number of embodiments of the present disclosure. The non-zero selection circuitry 409 is analogous to non-zero selection circuitry 109 and 309 illustrated in FIGS. 1 and 3, respectively. Further, the logic circuits 235-n, . . . , 235-(n+2) illustrated in FIG. 2 are part of the non-zero selection circuitry 409.

Although two circuit blocks (e.g., circuit blocks 440-1, 440-2) are illustrated in FIG. 4, embodiments are not limited to a particular quantity of circuit blocks that non-zero selection circuitry 409 can include. As illustrated in FIG. 4, a circuit block 440-1 can be structurally analogous to a circuit block 440-2. For example, logic gates 452-1, 454-1. 456-1 and a selector 458-1 of the circuit block 440-1 can be analogous to logic gates 452-2, 454-2. 456-2 and a selector 458-2 of the circuit block 440-2.

As illustrated in FIG. 4, the circuit block 440-1 receives a signal 441 (e.g., “0” shown in FIG. 4 and alternatively referred to as “activation signal”) at logic gates 454-1 and 456-1 of the circuit block 440-1. As described in connection with FIG. 3, a ground voltage received at the circuit block 440-1 can be taken as an activation signal. The activation signal causes the non-zero selection circuitry 409 to search for and output non-zero words (to the host 102 illustrated in FIG. 1) among those words respectively received at circuit blocks (e.g., circuit blocks 440-1 and 440-2) of the non-zero selection circuitry 409. As illustrated in FIG. 4, the activation signal is received at the logic gate 454-1 as inverted.

The logic gate 454-1 further receives an input signal (alternatively referred to as “output signal” from a logic gate 452-1) from the logic gate 452-1. Although embodiments are not so limited, the logic gate 452-1 (and/or 452-2) can be an wired OR circuit that receives more than two input signals so as to perform multiple logical OR operations and generates a single output signal as a result of the logical OR operations. For example, if at least one of the input signals corresponds to a logical “1”, the generated output signal corresponds to a logical “1”; however, if all of the input signals corresponds to a logical “0”, the generated output signal corresponds to a logical “0”.

Accordingly, the signal received from the logic gate 452-1 can be indicative of whether a word “D[0:15]” is non-zero (e.g., the signal from the logic gate 452-1 being a logical “1”) or not (e.g., the signal from the logic gate 452-1 being a logical “0”). The logic gate 454-1 provides an output signal (alternatively referred to as “input signal” from the logic gate 454-1) to a selector 458-1 to either enable or disable the selector 458-1. For example, with the logic gate 454-1 being an AND gate as illustrated in FIG. 4 and given that the activation signal being a logical “0”, the logic gate 454-1 further provides an output signal (e.g., being a logical “1”) to the selector 458-1 to enable the selector 458-1 when the signal communicated between the logic gates 452-1 and 454-1 indicates that the word “D[0:15]” is non-zero (e.g., the input signal being a logical “1”). The enabled selector 458-1 can output the word “D[0:15]” on the LIO line 438 (e.g., LIO 238-1 or LIOF 238-2 illustrated in FIG. 2). On the other hand, the output signal (e.g., being a logical “0”) from the logic gate 454-1 can cause the selector 458-1 to be disabled, which prevents the word “D[0:15]” to be outputted on the LIO line 438.

The output signal of the logic gate 454-1 can be further provided to the logic gate 456-1 as an input signal. Although embodiments are not so limited, the logic gate 456-1 (and/or 456-2) can be an OR gate. An output signal of the logic gate 456-1 (alternatively referred to as “input signal” to the circuit block 440-2) can be provided to (e.g., logic gates 454-2 and 456-2 of) the circuit block 440-2 can either inhibit the circuit block 440-2 (when the output signal of the logic gate 456-1 corresponds to a logical “1”) or allow the circuit block 440-2 to output a word “D[16:31]” (when the output signal of the logic gate 456-1 corresponds to a logical “0”).

For example, in response to the signal received from the logic gate 454-1 having a logical “0” (indicating that the word “D[0:15]” is determined to be a zero word) and given that the logic gate 456-1 is an OR gate, the logic gate 456-1 outputs a signal having a logical “0” with which a word “D[16:31]” can be outputted on the LIO line 438 when the word “D[16:31]” is determined to be a non-zero word. On the other hand, in response to the signal received from the logic gate 454-1 having a logical “1” (indicating that the word “D[0:15]” is determined to be a non-zero word), the logic gate 456-1 outputs a signal having a logical “1” with which the circuit block 440-2 is inhibited. While the circuit block 440-2 is inhibited, a corresponding word (e.g., the word “D[16:31]”) is prevented from being outputted on the LIO line 438 regardless of whether the word “D[16:31]” is a non-zero or not.

When allowed by the circuit block 440-1, the circuit block 440-2 operates in a similar manner as the circuit block 440-1. For example, the circuit block 440-3 can inhibit a subsequent circuit block (e.g., coupled via the logic gate 456-2) in response to the word “D[16:31]” being determined to be a non-zero word or allow the subsequent circuit block to output a corresponding word (when the corresponding word is determined to be a non-zero word).

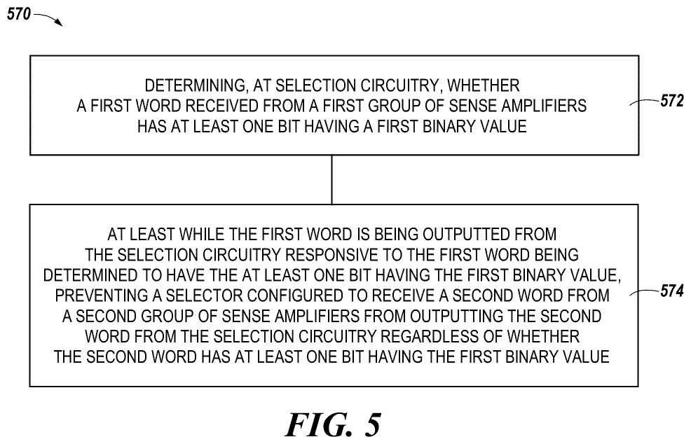

FIG. 5 is a flow diagram that illustrates an example method 570 for programming multiple erase blocks coupled to a same string in accordance with various embodiments of the present disclosure. The method 570 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 570 is performed by the non-zero selection circuitry 109, 309, and 409 of FIGS. 1 and 3-4 and/or the controller 110 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 572, a first word (e.g., a word “D[0:15]” illustrated in FIGS. 3 and 4) can be examined (at non-zero selection circuitry, such as non-zero selection circuitry 109, 309, 409 illustrated in FIGS. 1 and 3-4) to determine whether the first word received from a first group of sense amplifiers (e.g., sense amplifiers 108, 208 illustrated in FIGS. 1-2) has at least one bit having a first binary value (e.g., a logical “1”). In some embodiments, the non-zero selection circuitry 109, 309, 409 includes a first circuit block (e.g., a circuit block 340-1, 440-1 illustrated in FIGS. 3-4) to receive the first word and a second circuit block (e.g., a circuit block 340-2, 440-2 illustrated in FIGS. 3-4) to receive a second word (e.g., a word “D[16:31]” illustrated in FIGS. 3 and 4 and/or a word “D[N-16:N]” illustrated in FIG. 3). In this example, the method can further include putting the first circuit block 340-1, 440-1 into a high impedance state responsive to the first word being determined to not have the at least one bit having the first binary value.

At block 574, at least while the first word is being outputted from the non-zero selection circuitry 109, 309, 409 responsive to the first word being determined to have the at least one bit having the first binary value, a selector, such as a selector 458-2 illustrated in FIG. 4 (that is configured to receive the second word from a second group of sense amplifiers, such as sense amplifiers 108, 208 illustrated in FIGS. 1-2, from outputting the second word) can be prevented from outputting the second word from the non-zero selection circuitry 109, 309, 409 regardless of whether the second word has at least one bit having the first binary value. In some embodiments, responsive to the first word being determined to not have the at least one bit having the first binary value, the selector 458-2 can be allowed to output the second word from the non-zero selection circuitry 109, 309, 409 if the second word is determined to have the at least one bit having the first binary value. In some embodiments, the non-zero selection circuitry 109, 309, 409 can be further coupled to a local input/output (LIO) line (e.g., the LIO/LIOF lines 238-1 and 238-2, 338, 438 illustrated in FIGS. 2-4). In this example, the method 570 further includes outputting the first word on the LIO line 238, 338, 438 responsive to the first word being determined to have the at least one bit having the first binary value.

In some embodiments, the first word can be replaced with a number of bits not having the first binary value (e.g., a “zero” word) responsive to the first word having been outputted from the non-zero selection circuitry 109, 309, 409. The selector 458-2 can be allowed to output the second word from the non-zero selection circuitry 109, 309, 409 responsive to the first word being replaced with the number of bits. Continuing with this example, the second word can be examined at the non-zero selection circuitry 109, 309, 409 to determine whether the second word has at least one bit having the first binary value responsive to the first word being determined to not have the at least one bit having the first binary value or being replaced with the number of bits. Further, responsive to the second word being determined to have the at least one bit having the first binary value, a selector (that is configured to receive a third word from a third group of sense amplifiers) can be prevented from outputting the third word from the non-zero selection circuitry 109, 309, 409 at least while the second word is being outputted from the non-zero selection circuitry 109, 309, 409 regardless of whether the third word has at least one bit having the first binary value.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
determining, at selection circuitry, whether a first word received from a first group of sense amplifiers has at least one bit having a first binary value; and
at least while the first word is being outputted from the selection circuitry responsive to the first word being determined to have the at least one bit having the first binary value, preventing a selector configured to receive a second word from a second group of sense amplifiers from outputting the second word from the selection circuitry regardless of whether the second word has at least one bit having the first binary value.

2. The method of claim 1, further comprising:
responsive to the first word being determined to not have the at least one bit having the first binary value, allowing the selector to output the second word from the selection circuitry if the second word is determined to have the at least one bit having the first binary value.

3. The method of claim 1, further comprising:
replacing the first word with a number of bits not having the first binary value responsive to the first word having been outputted from the selection circuitry; and
responsive to the first word being replaced with the number of bits, allowing the selector to output the second word from the selection circuitry.

4. The method of claim 3, further comprising:
determining, at the selection circuitry, whether the second word has at least one bit having the first binary value responsive to the first word being determined to not have the at least one bit having the first binary value or being replaced with the number of bits; and
responsive to the second word being determined to have the at least one bit having the first binary value, preventing a selector configured to receive a third word from a third group of sense amplifiers from outputting the third word from the selection circuitry at least while the second word is being outputted from the selection circuitry regardless of whether the third word has at least one bit having the first binary value.

5. The method of claim 1, wherein:
the selection circuitry further comprises a first circuit block to receive the first word and a second circuit block to receive the second word; and
the method further comprises putting the first circuit block into a high impedance state responsive to the first word being determined to not have the at least one bit having the first binary value.

6. The method of claim 1, wherein:
the selection circuitry is further coupled to a local input/output (LIO) line; and
the method further comprises outputting the first word on the LIO line responsive to the first word being determined to have the at least one bit having the first binary value.

7. An apparatus, comprising:
a memory array;
a plurality of sense amplifiers coupled to the memory array; and
selection circuitry coupled to the plurality of sense amplifiers, the selection circuitry comprising:
a first circuit block configured to receive a first word from a first group of sense amplifiers; and
a second circuit block configured to receive a second word from a second group of sense amplifiers; and
the first circuit block further configured to:
determine whether the first word has at least one bit having a first binary value; and
in response to the first word being determined to not have the at least one bit having the first binary value, provide a enable signal to the second circuit block to allow the second word to be outputted from the second circuit block when the second word is determined at the second circuit block to have at least one bit having the first binary value.

8. The apparatus of claim 7, wherein the first circuit block of the selection circuitry further comprises a first logic gate configured to:
receive the first word from the first group of sense amplifiers; and
determine whether the first word has the at least one bit having the first binary value.

9. The apparatus of claim 8, wherein the first logic gate is a wired OR circuit.

10. The apparatus of claim 8, wherein the first circuit block of the selection circuitry further comprises a second logic gate coupled to the first logic gate and a selector, the second logic gate configured to:
receive, from the first logic gate, an input signal indicating that the first word has the at least one bit having the first binary value; and
enable the selector to allow the first word to be outputted via the selector when the first word being is determined to have the at least one bit having the first binary value.

11. The apparatus of claim 10, wherein the second logic gate is an AND gate.

12. The apparatus of claim 10, wherein the first circuit block of the selection circuitry further comprises a third logic gate configured to:
receive, from the second logic gate, an input signal indicating that the first word is determined to have the at least one bit having the first binary value; and
provide the enable signal to the second circuit block of the selection circuitry.

13. The apparatus of claim 12, wherein the third logic gate is an OR gate.

14. The apparatus of claim 7, wherein:
the first and second circuit blocks of the selection circuitry are further coupled to a local input/output (LIO) line; and
the first and second circuit blocks are configured to output respective words on the LIO line.

15. The apparatus of claim 7, wherein the memory array comprises a dynamic random access memory (DRAM) array.

16. The apparatus of claim 7, wherein the selection circuitry is on-chip with the memory array and the plurality of sense amplifiers.

17. An apparatus, comprising:
a plurality of sense amplifiers; and
selection circuitry coupled to the plurality of sense amplifiers and to one or more local input/output (LIO) lines; and
the selection circuitry configured to determine, in response to receiving an activation signal, whether a first word received at the selection circuitry from a first group of sense amplifiers of the plurality has at least one bit having a first binary value;
wherein the activation signal further causes the selection circuitry to determine whether a second word received at the selection circuitry from a second group of sense amplifiers of the plurality has at least one bit having the first binary value when the first word is determined to not have the at least one bit having the first binary value.

18. The apparatus of claim 17, wherein the selection circuitry is configured to prevent, in response to the first word being determined to have the at least one bit having the first binary value, the second word from being outputted from the selection circuitry.

19. The apparatus of claim 18, further comprising a controller coupled to the selection circuitry and the plurality of sense amplifiers, wherein the controller is further configured to, in response to the first word being outputted on a respective one of the LIO lines:
replace the first word with a number of bits not having the first binary value to cause the selection circuitry to output the second word when the second word is determined to have at least one bit having the first binary value.

20. The apparatus of claim 19, wherein the selection circuitry is configured to output the second word without the first word being replaced with the number of bits when the first word is determined to not have the at least one bit having the first binary value.
